(19) United States
(12) Patent Application Publication
(10) Pub. No.: US 2020/0273878 A1
(43) Pub. Date: Aug. 27, 2020

(54) SEMICONDUCTOR DEVICE AND METHOD FOR PRODUCING THE SAME

(71) Applicant: TOSHIBA MEMORY CORPORATION, Tokyo (JP)

(72) Inventor: Takaya ISHINO, Yokkaichi Mie (JP)

(73) Assignee: TOSHIBA MEMORY CORPORATION, Tokyo (JP)

(21) Appl. No.: 16/553,435

(22) Filed: Aug. 28, 2019

(30) Foreign Application Priority Data
Feb. 25, 2019 (JP) 2019-031910

(51) Int. Cl. H01L 27/11582; G11C 5/06

(52) U.S. Cl. CPC H01L 27/11582; G11C 5/063

(57) ABSTRACT

According to one embodiment, a semiconductor device includes: a substrate; a stacked body that includes a conductive layer and an insulating layer which are alternately stacked in a first direction with respect to the substrate; a memory film that extends through the stacked body in the first direction and includes a charge storage layer; a separating section that extends in a second direction perpendicular to the first direction and includes an insulating film dividing the stacked body; and an insulating element that extends in a third direction perpendicular to the first direction and the second direction and has an upper end whose area is larger than the area of an upper end of the memory film.

### CROSS-REFERENCE TO RELATED APPLICATION(S)

This application is based upon and claims the benefit of priority from Japanese Patent Application No. 2019-031910, filed Feb. 25, 2019, the entire contents of which are incorporated herein by reference.

### FIELD

Embodiments described herein relate generally to semiconductor devices and methods for producing the semiconductor device.

### BACKGROUND

Production of three-dimensional semiconductor memory, which is an example of a semiconductor device, includes a process of forming a hole in a conductive layer and an insulating layer by dry etching. In such a dry etching process, an increase in the aspect ratio of the hole can cause a flow of a current into the insulating layer and result in dielectric breakdown. Examples of related art include JP-A-2013-080909.

### DESCRIPTION OF THE DRAWINGS

FIG. 1 is a schematic plan view of a semiconductor device according to a first embodiment;

FIG. 2 is a sectional view taken along the cutting-plane line A-A depicted in FIG. 1;

FIG. 3 is a sectional view depicting an example of the structure of a memory film;

FIG. 4 is a sectional view illustrating a stacked body formation process;

FIG. 5 is a sectional view illustrating an insulating film formation process;

FIG. 6 is a sectional view illustrating a mask formation process;

FIG. 7 is a sectional view illustrating an RIE process;

FIG. 8 is a sectional view showing holes which are being formed;

FIG. 9 is a sectional view showing the completion of the holes;

FIG. 10 is a sectional view depicting a state after the removal of an insulating film and a mask; and

FIG. 11 is a schematic plan view of a semiconductor device according to a second embodiment.

### DETAILED DESCRIPTION

Embodiments provide a semiconductor device in which dielectric breakdown is less likely to occur and a method for producing the semiconductor device.

In general, according to one embodiment, a semiconductor device includes: a substrate; a stacked body that includes a conductive layer and an insulating layer which are alternately stacked in a first direction with respect to the substrate; a memory film that extends through the stacked body in the first direction and includes a charge storage layer; a separating section that extends in a second direction perpendicular to the first direction and includes an insulating film separating the stacked body from another stacked body; and an insulator that extends in a third direction perpendicular to the first direction and the second direction and has an upper end with an area greater than the area of an upper end of the memory film.

Hereinafter, embodiments of the present disclosure will be described with reference to the drawings. The embodiments are not intended for limitation.

### First Embodiment

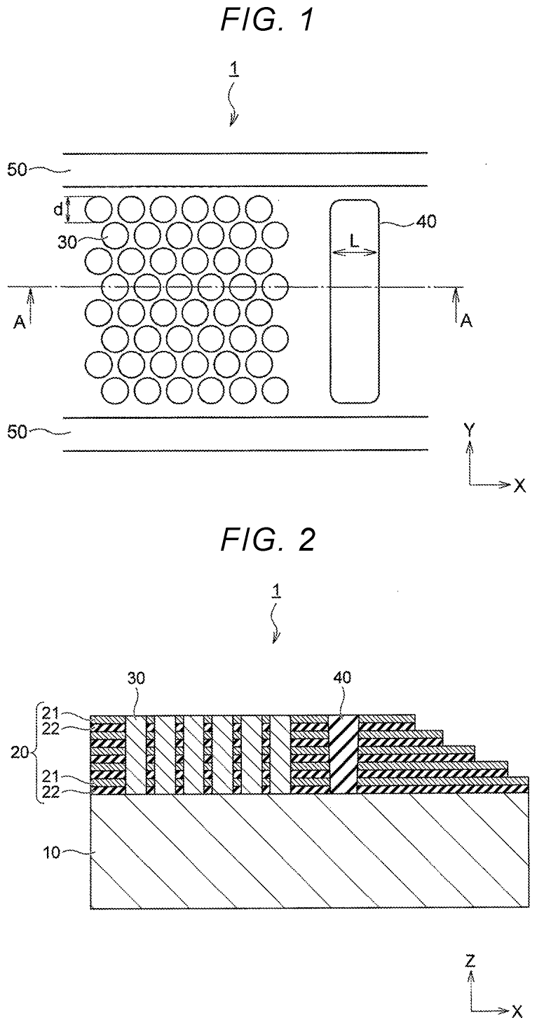

FIG. 1 is a schematic plan view of a semiconductor device according to a first embodiment. FIG. 2 is a sectional view taken along the cutting-plane line A-A depicted in FIG. 1. A semiconductor device 1 depicted in FIGS. 1 and 2 is an example of three-dimensional semiconductor memory in which memory cells are stacked. This semiconductor device 1 includes a semiconductor substrate 10, a stacked body 20, a memory film 30, an insulating element 40, and a separating section 50. In FIG. 2, a contact, an interlayer insulating film, upper layer wiring, and so forth which are formed on a step-like end of the stacked body 20 are not depicted.

The semiconductor substrate 10 is, for example, a silicon substrate. On the semiconductor substrate 10, the stacked body 20 is provided. A wiring layer including, for instance, a drive circuit for the memory film 30 may be formed between the semiconductor substrate 10 and the stacked body 20.

As depicted in FIG. 2, the stacked body 20 includes a plurality of conductive layers 21 and a plurality of insulating layers 22. The plurality of conductive layers 21 and the plurality of insulating layers 22 are alternately stacked in a Z direction (a first direction). Each conductive layer 21 contains metal such as tungsten (W), for example, and functions as a word line. On the other hand, each insulating layer 22 contains silicon dioxide (SiO₂), for example. Moreover, an end of the stacked body has a step-like shape to electrically connect each conductive layer 21 to external wiring.

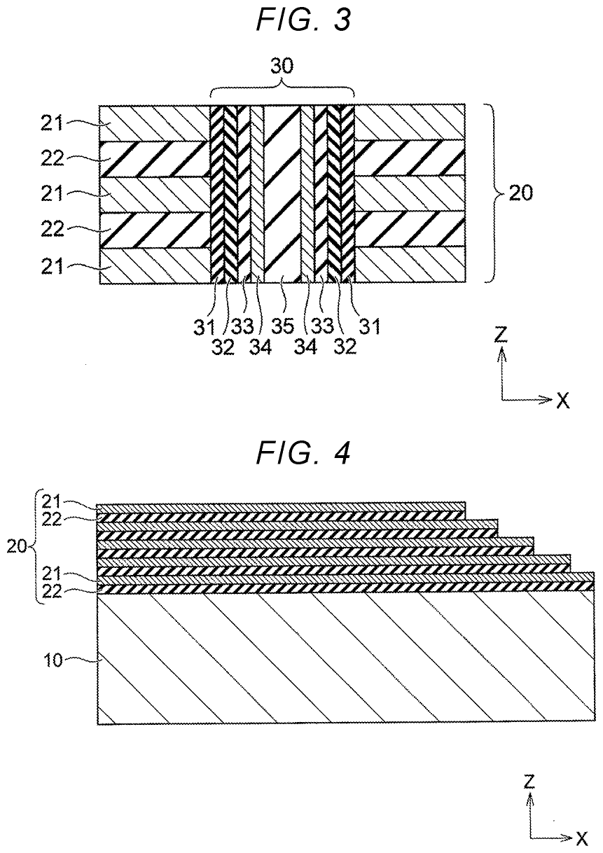

The memory film 30 is an example of a memory film passing through the stacked body 20 in the Z direction. In the present embodiment, the upper end face of the memory film 30 is a circle. That is, the memory film 30 is a cylinder. Here, the structure of the memory film 30 will be described with reference to FIG. 3.

FIG. 3 is a sectional view depicting an example of the structure of the memory film 30. In the memory film 30 depicted in FIG. 3, a charge block film 31, a charge storage film 32, a tunnel insulating layer 33, a channel film 34, and a core film 35 are stacked in this order. With this configuration, in the height positions of the conductive layers 21, memory cells, each including the charge storage film 32, are arranged in the height direction of the core film 35. The memory cell stores data in a nonvolatile manner depending on the presence or absence of a charge which is stored in the charge storage film 32.

The charge block film 31, the tunnel insulating layer 33, and the core film 35 are each formed as a silicon oxide film, for example. The charge storage film 32 is formed as a silicon nitride film (SiN), for example. The channel film is formed as a polysilicon film, for example. The structure of the memory film 30 is not limited to the structure depicted in FIG. 3.

As depicted in FIGS. 1 and 2, the insulating element faces the memory film 30 in an X direction (a second direction) perpendicular to the Z direction and passes through the stacked body 20. The insulating element 40 contains silicon dioxide, for example.

As depicted in FIG. 1, the upper end face of the insulating element 40 is a rectangle with short side portions, which extend in the X direction, and long side portions, which extend in a Y direction (a third direction) perpendicular to the X direction and the Z direction. The length L of each of the above-described short side portions is longer than the diameter d of the upper end face of the memory film 30 which is a circle. In other words, the area of the upper end face of the insulating element 40 is larger than the area of the upper end face of the memory film 30. The first embodiment deals with the memory film 30 whose outer periphery is a circle; however, the shape of the outer periphery of the memory film 30 is not limited to a particular shape. As will be described later, the outer periphery of the memory film 30 may be an ellipse.

Moreover, as depicted in FIG. 2, in the present embodiment, the insulating element 40 is formed between the memory film 30 and the step-like end of the stacked body 20. The position in which the insulating element 40 is formed is not limited to a particular position as long as the insulating element 40 is connected to the memory film 30 via a common conductive layer 21.

The separating section 50 faces the memory film 30 in the Y direction. The separating section 50 contains silicon dioxide, for example. In FIG. 1, two separating sections 50 extend in the X direction with a memory region, in which a plurality of memory films 30 are arranged, placed therebetween. As a result, this memory region is separated from other memory regions. The separating section 50 may be configured with an insulator such as silicon dioxide or may have a configuration in which a conductor is formed in an insulating film. This conductor is connected to a source line that drives the memory film 30, for instance.

Hereinafter, a production process of the above-described semiconductor device 1 will be described.

First, as depicted in FIG. 4, the stacked body 20 with a step-like end is formed on the semiconductor substrate 10. The stacked body 20 is formed by alternately forming the conductive layer 21 and the insulating layer 22 by chemical vapor deposition (CVD) or atomic layer deposition (ALD), for example.

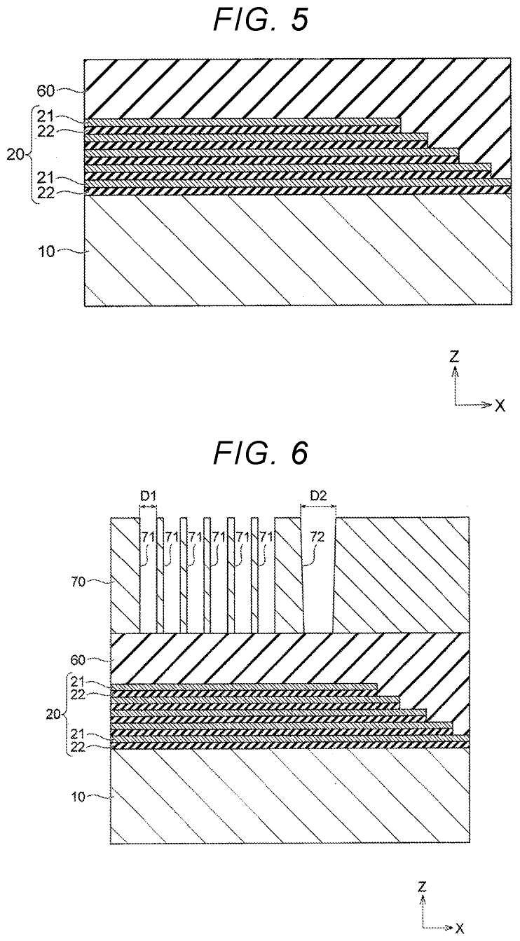

Next, as depicted in FIG. 5, an insulating film 60 is formed on the stacked body 20. The insulating film 60 is formed as a silicon dioxide film by applying plasma or heat to tetraethoxysilane (TEOS), for instance.

Then, as depicted in FIG. 6, a mask 70 is formed on the insulating film 60. The mask 70 is formed as a carbon film by using plasma CVD, for example. In the mask 70, a pattern with holes 71 and a groove 72 is formed as depicted in FIG. 6. The holes 71 are formed on an area in which the memory films 30 will be formed. On the other hand, the groove 72 is formed on an area in which the insulating element 40 will be formed. Moreover, the opening diameter D2 of the groove 72 is larger than the opening diameter D1 of each hole 71. In other words, the aspect ratio (opening diameter/depth) of the groove 72 is lower than the aspect ratio of the hole 71.

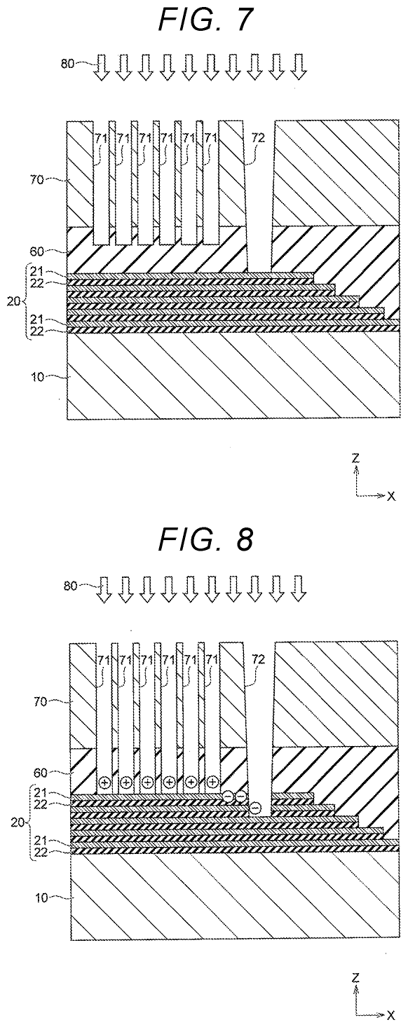

Next, as depicted in FIG. 7, reactive ion etching (RIE) by which the mask 70 is irradiated with ions 80 is performed. As a result, the insulating film 60 is etched based on the pattern of the mask 70. In this case, since the opening diameter D2 of the groove 72 is larger than the opening diameter D1 of the hole 71, the etching rate at which the insulating film 60 immediately below the groove 72 is etched is higher than the etching rate at which the insulating film 60 immediately below the holes 71 is etched. As a result, as depicted in FIG. 7, the bottom of the groove 72 reaches the stacked body 20 earlier than the holes 71.

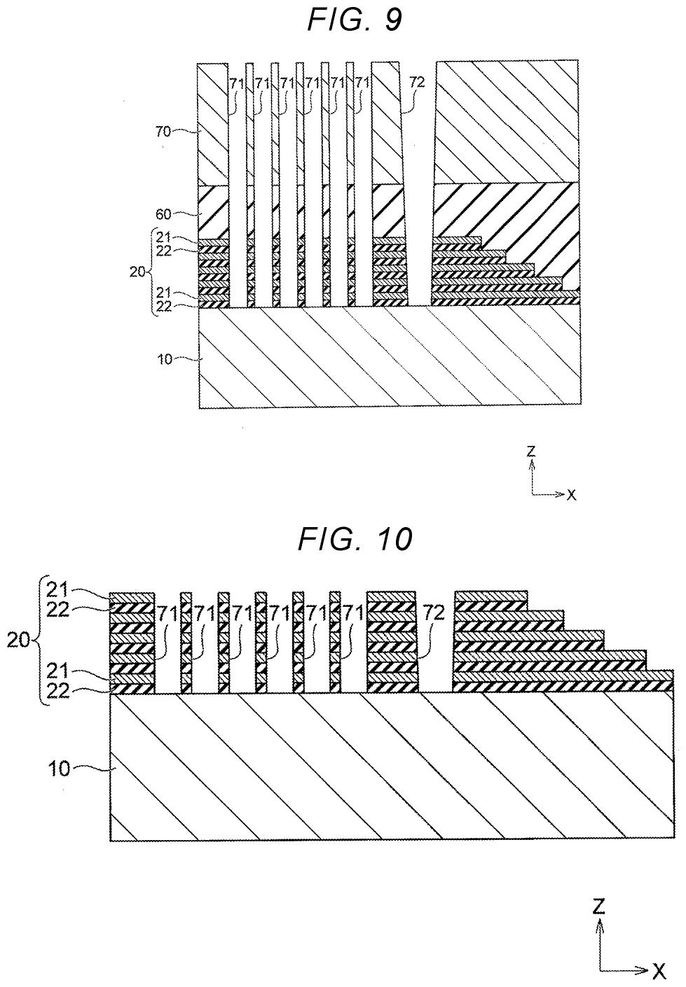

Irradiation with the ions 80 is then performed continuously and, as depicted in FIG. 8, the bottoms of the holes 71 also reach the stacked body 20. The bottom of the groove 72 already reaches the inside of the stacked body 20 at this point. Then, as depicted in FIG. 9, when the holes 71 and the groove 72 pass through the stacked body 20 and reach the semiconductor substrate 10, irradiation with the ions 80 is finished. Then, as depicted in FIG. 10, the mask 70 and the insulating film 60 are removed. Since the groove 72 exposes the semiconductor substrate 10 earlier than the holes 71, the bottom of the groove 72 may penetrate into an upper portion of the semiconductor substrate 10.

Next, the memory films 30 are formed in the holes 71 passing through the stacked body 20. Moreover, the insulating element 40 is embedded in the groove 72 passing through the stacked body 20. The order in which the memory films 30 and the insulating element 40 are formed is not limited to a particular order. Moreover, the formation of a slit (which is not depicted in the drawing) in which the separating section 50 will be embedded may be performed before the formation of the holes 71 and the groove 72 in the stacked body 20 or after the formation of these holes and groove.

In the semiconductor device 1 according to the present embodiment described above, if the number of stacked layers of the stacked body 20 is large, the energy of the ions 80 is also increased. Therefore, positive charges tend to accumulate in the conductive layer 21 on the bottom of the hole 71 during the formation of the hole 71. If a large number of positive charges accumulates, a current flows into the insulating layer 22 from the conductive layer 21, which can cause a breakdown of the insulating layer 22.

Thus, in the present embodiment, the formation of the hole 71 in which the memory film 30 will be formed and the formation of the groove 72 whose aspect ratio is lower than the aspect ratio of the hole 71 are started at the same time. In this case, as depicted in FIG. 8, since the aspect ratio of the groove 72 is lower than the aspect ratio of the hole 71, more electrons can enter the groove 72. Therefore, even when positive charges accumulate in the hole 71, the electrons in the groove 72 are attracted to the positive charges via the conductive layer 21, which causes the charges to be distributed less unevenly. As a result, arcing is less likely to occur and therefore a breakdown of the insulating layer 22 can be prevented.

### Second Embodiment

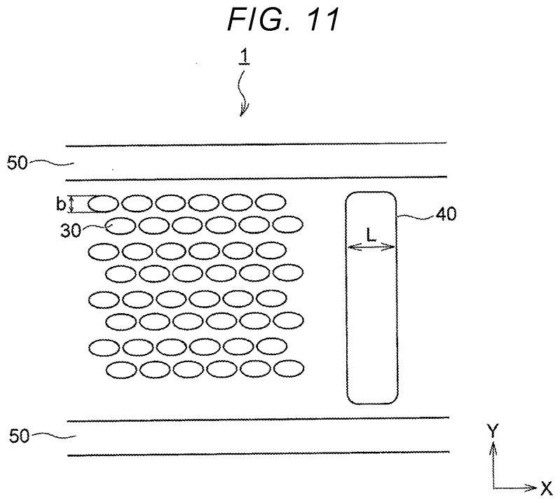

FIG. 11 is a schematic plan view of a semiconductor device according to a second embodiment. Elements similar to the elements of the above-described first embodiment are identified with the same reference signs and detailed explanations thereof will be omitted.

As depicted in FIG. 11, in a semiconductor device 2 according to the present embodiment, the upper end face of each memory film 30 is an ellipse which is defined by a major axis extending in the X direction and a minor axis extending in the Y direction. That is, the memory film 30 is an elliptic cylinder. As in the case of the first embodiment, the memory film 30 is formed in the hole 71. To form the memory film 30 in the shape of an elliptic cylinder, the aperture of the hole 71 is shaped like an ellipse in the present embodiment.

On the other hand, the upper end face of the insulating element 40 is a rectangle as in the case of the first embodiment. In the present embodiment, the length L of each of the short side portions of the insulating element 40 is longer than the length b of the minor axis of the upper end face, which is an ellipse, of the memory film 30. In other words, also in the present embodiment, the area of the upper end face of the insulating element 40 is larger than the area of the upper end face of the memory film 30.

As in the case of the first embodiment, the insulating element 40 is formed in the groove 72. Therefore, also in the present embodiment, the groove 72 reaches the stacked body 20 earlier than the holes 71 and electrons enter the groove 72. As a result, since the positive charges accumulated in the hole 71 attract the electrons, which causes the charges to be distributed less unevenly, the occurrence of arcing is prevented and therefore a breakdown of the insulating layer 22 can be prevented.

In the above-described first and second embodiments, the groove 72 is formed concurrently with the formation of the holes 71 passing through the stacked body 20 configured with the conductive layers 21 and the insulating layers 22; however, applications of the groove 72 are not limited to the process of forming the memory films 30. For example, the groove 72 can also be applied to a process of forming a hole in a single-layer insulating layer and stopping etching at a conductive layer. Also in this application, the formation of the groove 72 can produce a similar effect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a stacked body that includes a conductive layer and an insulating layer that are alternately stacked in a first direction with respect to the substrate;
a memory film that extends through the stacked body in the first direction and includes a charge storage layer;
a separating section that extends in a second direction perpendicular to the first direction and includes an insulating film separating the stacked body from another stacked body; and
an insulator that extends in a third direction perpendicular to the first direction and the second direction and has an upper end with an area greater than an area of an upper end of the memory film.

2. The semiconductor device according to claim 1, wherein
the stacked body is provided between the separating section and the insulator.

3. The semiconductor device according to claim 1, wherein
the stacked body has a step-like end, and
the insulator is provided between the memory film and the step-like end.

4. The semiconductor device according to any one of claim 1, wherein
a shape of the upper end of the memory film is a circle.

5. The semiconductor device according to claim 4, wherein
a shape of the upper end of the insulator is a rectangle, and
a length of a short side of the rectangle is greater than a diameter of the circle.

6. The semiconductor device according to claim 1, wherein
a shape of the upper end of the memory film is an ellipse.

7. The semiconductor device according to claim 6, wherein
a shape of the upper end of the insulator is a rectangle, and
a length of a short side of the rectangle is greater than a length of a minor axis of the ellipse.

8. A method for producing a semiconductor device, comprising:
stacking a conductive layer and an insulating layer in a first direction;
concurrently begin forming (i) a hole that passes through the conductive layer and the insulating layer and (ii) a groove parallel to the hole, passes through the conductive layer and the insulating layer, and has an opening diameter larger than an opening diameter of the hole;
forming a memory film in the hole, wherein the memory film includes a charge storage layer; and
forming an insulator in the groove.

9. The method for producing a semiconductor device according to claim 8, further comprising:
forming an insulating film that covers the conductive layer; and
forming, on the insulating film, a mask with a first pattern and a second pattern.

10. The method for producing a semiconductor device according to claim 9, further comprising:
etching the insulating film through the first pattern and second pattern to expose a portion of the insulating layer where the groove is to be formed.

11. The method for producing a semiconductor device according to claim 10, further comprising:
irradiating, with ions, the insulating film, the conductive layer and the insulating layer through the first pattern and second pattern to form the hole and the groove, respectively.
